(19) United States
(12) Patent Application Publication
(10) Pub. No.: US 2025/0356903 A1
(43) Pub. Date: Nov. 20, 2025

(54) HIGH BANDWIDTH MEMORY DEVICE BANDWIDTH SCALING AND ASSOCIATED SYSTEMS AND METHODS

(71) Applicant: Micron Technology, Inc., Boise, ID (US)

(72) Inventor: Sujeet Ayyapureddi, Boise, ID (US)

(21) Appl. No.: 19/201,673

(22) Filed: May 7, 2025

Related U.S. Application Data
(60) Provisional application No. 63/647,466, filed on May 14, 2024.

(51) Int. Cl. G11C 11/4076; G11C 11/4093

(52) U.S. Cl. CPC G11C 11/4076; G11C 11/4093

(57) ABSTRACT

A SiP device can include a base substrate and a processing unit. The SiP can also include a HBM device that includes dies that each have one or more bank groups. The HBM device can include a HBM memory controller circuit configured to select different bank groups. The different bank groups can correspond to a same channel or a same pseudo-channel for read/write operations during a t_{CCDL} CLK cycle period. Each bank group can be selected during a different t_{CCDS} CLK cycle period within the t_{CCDL} CLK cycle period. The HBM memory controller circuit can be configured to selectively and communicatively couple a TSV bus to each selected bank group of the different bank groups, and the selected bank group can be communicatively coupled to the TSV bus for a duration of the respective t_{CCDS} CLK cycle period. In some cases, a timing ratio of t_{CCDL}/t_{CCDS} can be greater than 2.

### CROSS-REFERENCE TO RELATED APPLICATION(S)

The present application claims priority to U.S. Provisional Patent Application No. 63/647,466, filed May 14, 2024, the disclosure of which is incorporated herein by reference in its entirety.

### TECHNICAL FIELD

The present technology is generally related to vertically stacked semiconductor devices and more specifically to vertically stacked high bandwidth storage devices for semiconductor packages.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, imager devices, interconnecting circuitry, etc. To meet continual demands on decreasing size, wafers, individual semiconductor dies, and/or active components are typically manufactured in bulk, singulated, and then stacked on a support substrate (e.g., a printed circuit board (PCB) or other suitable substrates). The stacked dies can then be coupled to the support substrate (sometimes also referred to as a package substrate) through substrate (or silicon) vias (TSVs) between the dies and the support substrate.

### BRIEF DESCRIPTION OF THE DRAWINGS

FIG. 1 is a partially schematic cross-sectional diagram of a related art system-in-package device.

FIG. 2 is a simplified related art timing diagram for data flow through the TSVs.

FIG. 3A is a partially schematic cross-sectional diagram of a system-in-package device that is consistent with the present disclosure.

FIG. 3B is a block diagram of an embodiment of a HBM device that is consistent with the present disclosure.

FIG. 4 is a block diagram of an embodiment of a transmit/receive circuit that can be used in the TSVs of FIGS. 3A and 3B.

FIG. 5A is a simplified timing diagram for data flow through the DQ and TSV buses during write operations that is consistent with the present disclosure.

FIG. 5B is a simplified timing diagram for data flow through the DQ and TSV buses during read operations that is consistent with the present disclosure.

FIG. 6 is a flow chart that shows a method of configuring an HBM device that is consistent with the present disclosure.

The drawings have not necessarily been drawn to scale. Further, it will be understood that several of the drawings have been drawn schematically and/or partially schematically. Similarly, some components and/or operations can be separated into different blocks or combined into a single block for the purpose of discussing some of the implementations of the present technology. Moreover, while the technology is amenable to various modifications and alternative forms, specific implementations have been shown by way of example in the drawings and are described in detail below. The intention, however, is not to limit the technology to the particular implementations described.

### DETAILED DESCRIPTION

High data reliability, high speed of memory access, higher data bandwidth, lower power consumption, and reduced chip size are features that are demanded from semiconductor memory. In recent years, vertically stacked memory devices have been introduced, often referred to as 2.5-dimensional (“2.5D”) memory devices when placed adjacent to a host device or 3-dimensional (“3D”) memory devices when stacked on top of the host device. Some 2.5D and 3D memory devices are formed by stacking memory dies vertically and interconnecting the dies using through-silicon (or through-substrate) vias (TSVs). The memory dies can be grouped in “stacks” with each stack, designated by a stack ID (“SID”), having one or more dies (e.g., 4 dies). Benefits of the 2.5D and 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 2.5 and 3D memory devices contribute to higher memory access speed, lower power consumption, and chip size reduction. Example 2.5D and/or 3D memory devices include Hybrid Memory Cube (HMC) and High Bandwidth Memory (HBM). For example, HBM is a type of memory that includes a vertical stack of dynamic random-access memory (DRAM) dies and an interface die (which, e.g., provides the interface between the DRAM dies of the HBM device and a host device). In the description below, the terms “stack” and “SID” are used interchangeably.

In a system-in-package (SiP) configuration, HBM devices may be integrated with a host device (e.g., a graphics processing unit (GPU), computer processing unit (CPU), a tensor processing unit (TCU), and/or any other suitable processing unit) using a base substrate (e.g., a silicon interposer, a substrate of organic material, a substrate of inorganic material and/or any other suitable material that provides interconnection between GPU/CPU and the HBM device and/or provides mechanical support for the components of a SiP device) through which the HBM devices and host communicate. Because traffic between the HBM devices and host device resides within the SiP (e.g., using signals routed through the silicon interposer), a higher bandwidth may be achieved between the HBM devices and host device than in conventional systems. In other words, the TSVs interconnecting DRAM dies within an HBM device, and the silicon interposer integrating HBM devices and a host device, enable the routing of a greater number of signals (e.g., wider data buses) than is typically found between packaged memory devices and a host device (e.g., through a printed circuit board (PCB)). The high bandwidth interface within a SiP enables large amounts of data to move quickly between the host device (e.g., GPU/CPU/TCU, etc.) and HBM devices during operation. For example, the high bandwidth channels can be on the order of 1000 gigabytes per second (GB/s, sometimes also referred to as gigabits (Gb)). As a result, the SiP device can quickly complete computing operations once data is loaded into the HBM devices. SiP devices, in turn, are typically integrated with a package substrate (e.g., a PCB) adjacent to other electronics and/or other SiP devices within a packaged system. It will be appreciated that such high bandwidth data transfer between the host device and the memory of HBM devices can be advantageous in various high-performance computing applications, such as video rendering, high-resolution graphics applications, artificial intelligence and/or machine learning (AI/ML) computing systems and other complex computational systems, and/or various other computing applications.

Market demands on SiP devices and/or the HBM devices therein can present certain challenges, however. One such challenge is that demands on SiP devices (and the HBM devices therein) require the devices to continually increase bandwidth and corresponding DQ pin data rates. The increased data rates means that the data paths in the HBM device operate at tight timing margins. For example, the timing parameter t_{CCDR}, which corresponds to 2 CLK cycles, can degrade. In addition, increasing the bandwidth can mean changing the memory array timing, which is not desirable. Accordingly, it is desirable to increase the bandwidth on the HBM device while maintaining the same memory array timing and keeping t_{CCDR} CLK cycles at 2 CLK cycles. In addition, higher bandwidths mean running the HBM device faster (e.g., a faster system clock frequency), which results in increased power consumption.

As used herein, the terms “vertical,” “lateral,” “upper,” “lower,” “top,” and “bottom” can refer to relative directions or positions of features in the devices in view of the orientation shown in the drawings. For example, “bottom” can refer to a feature positioned closer to the bottom of a page than another feature. These terms, however, should be construed broadly to include devices having other orientations, such as inverted or inclined orientations where top/bottom, over/under, above/below, up/down, and left/right can be interchanged depending on the orientation.

Further, although primarily discussed herein in the context of 2.5 HBM devices for SiP devices, one of skill in the art will understand that the scope of the present disclosure is not so limited. For example, various components of the SiP devices described herein can also be implemented in 3D HBM devices and various other stacked semiconductor devices to help with issues related to high data rates as discussed above. Accordingly, the scope of the present disclosure is not confined to any subset of embodiments and is confined only by the limitations set out in the appended claims.

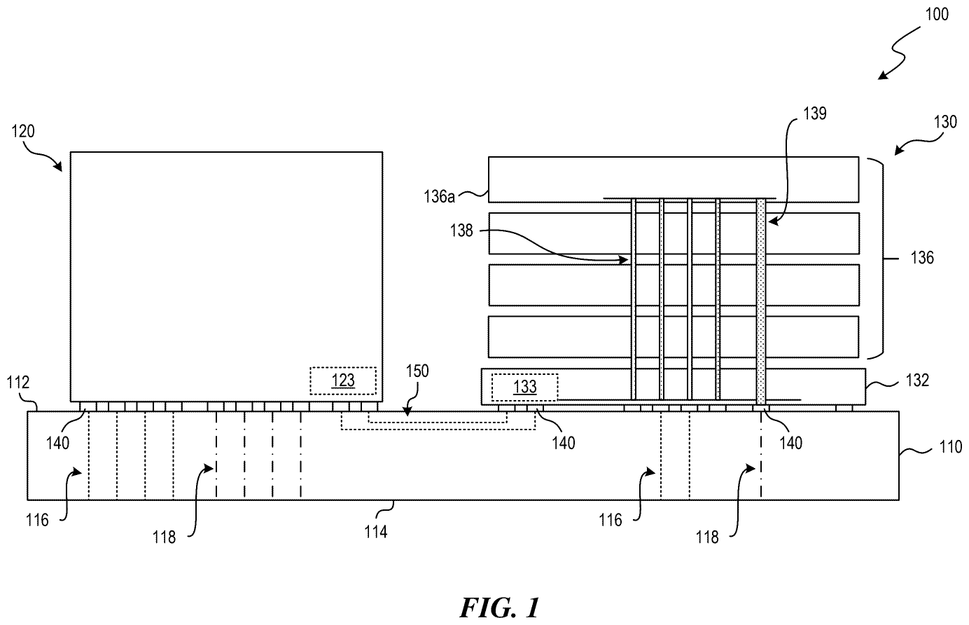

FIG. 1 is a partially schematic cross-sectional diagram of a related art SiP device 100. As illustrated in FIG. 1, the SiP device 100 includes a base substrate 110 (e.g., a silicon interposer, another organic interposer, an inorganic interposer, and/or any other suitable base substrate), as well as a host device 120 and an HBM device 130 each integrated with (e.g., carried by and coupled to) an upper surface 112 of the base substrate 110 through a plurality of interconnect structures 140 (three labeled in FIG. 1). The interconnect structures 140 can be solder structures (e.g., solder balls), metal-metal bonds, and/or any other suitable conductive structure that mechanically and electrically couples the base substrate 110 to each of the host device 120 and the HBM device 130. Further, the host device 120 is coupled to the HBM device 130 through one or more communication channels 150 formed in the base substrate 110. The communication channels 150 can include one or more route lines (two illustrated schematically in FIG. 1) formed into (or on) the base substrate 110.

As further illustrated in FIG. 1, the base substrate 110 includes a plurality of external signal TSVs 116 and a plurality of external power TSVs 118 extending between the upper surface 112 and a lower surface 114 of the base substrate 110. The external signal TSVs 116 can communicate signals (e.g., data, control signals, processing commands, and/or the like) between the host device 120 and/or the HBM device 130 and an external component (e.g., a PCB the base substrate 110 is integrated with, an external controller, and/or the like). The external power TSVs 118 provide electrical power to the host device 120 and/or the HBM device 130 from an external power source.

In the illustrated environment, the host device 120 can include a variety of components, such as a processing unit (e.g., CPU/GPU/TCU, etc.), one or more registers, one or more cache memories, and/or a variety of other components. For example, in the illustrated environment, the host device 120 includes a host IO circuit 123 that can direct signals to and/or from the HBM device 130 through the communication channels 150. Additionally, or alternatively, the host IO circuit 123 can direct signals to and/or from an external component (e.g., a controller coupled to one or more of the external signal TSVs 116 and/or the like).

The HBM device 130 can include an interface die 132 and a stack of one or more memory stacks 136 (four illustrated in FIG. 1) carried by the interface die 132. Each of the memory stacks 136 can include one or more DRAM dies (not shown in FIG. 1). Each memory stack 136 may encompass a physical and/or logical arrangement of one or more dies and can be associated with a stack ID (SID). The HBM device 130 also includes one or more signal TSVs 138 (four illustrated in FIG. 1) and one or more power TSVs 139 (one illustrated in FIG. 1) each extending from the interface die 132 to an uppermost memory stack 136a. The power TSV(s) 139 provide power (e.g., received from one or more of the external power TSVs 118) to the interface die 132 and each of the memory stacks 136. The signal TSVs 138, which include TSVs for carrying control, address, and DQ signals, communicably couple a corresponding memory die in each of the memory stacks 136 to a HBM memory controller circuit 133 in the interface die 132 (in addition to various other circuits in the interface die 132). In turn, the HBM memory controller circuit 133 can direct DQ, control, and/or address signals to and/or from the host device 120 and/or an external component (e.g., an external storage device coupled to one or more of the external signal TSVs 116 and/or the like).

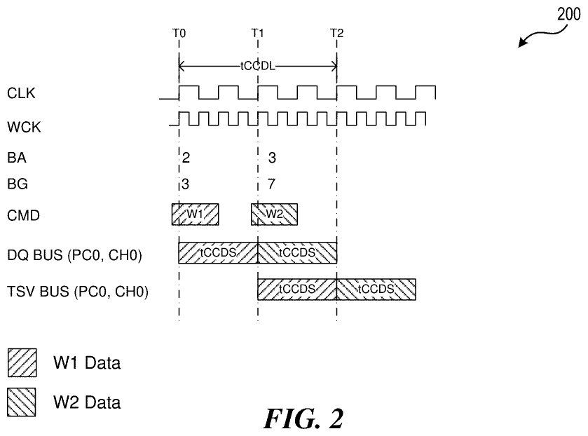

FIG. 2 illustrates a timing diagram 200 for a related art SiP that shows data transfer during a write operation using a set of TSVs (“TSV bus”). The timing diagram can correspond to a related art HBM device with a data rate of 8 Gbps. For brevity, a read timing diagram is not shown. As used herein a “TSV bus” can refer to one or more TSVs carrying DQ signals. For example, based on the context, a TSV bus can refer to all the TSVs or a subset of the TSVs in an HBM device (e.g., TSVs corresponding to a channel, a pseudo-channel, etc.). As seen in FIG. 2, the frequency of the system clock CLK determines the frequency of the write clock WCK, which can be, for example, twice the system CLK frequency. The WCK signal provides the timing for data transfer using, for example, double data rate (DDR). That is, data transfers occur on both the rising and falling edges of the WCK clock.

The CLK signal determines the duration of timing parameters, such as for example, column access timing parameters t_{CCDL}, t_{CCDS} and t_{CCDR}, which can be set according to the standard for the HBM device. The timing parameter t_{CCDL} is the read/write (RD/WR) command delay between different banks (BAs) within the same bank group (BG), the timing parameter t_{CCDS} is the RD/WR command delay between different BGs, and the timing parameter t_{CCDR} is the RD command delay between different SIDs. The host device and the HBM device communicate using an interface protocol, which is provided to and/or configured in the host device prior to the start of memory operations. The timing parameters are part of the interface protocol between a host device and HBM device, and the HBM device may provide to the host device the timing requirements for scheduling memory operations. That is, the HBM device may let the host device know the CLK cycle settings for timing parameters such as, for example, t_{CCDL} and t_{CCDS}. The host device observes any restrictions in the timing parameters when communicating with the HBM device. For example, based on the t_{CCDL} timing parameter, the host device will not schedule read or write commands to banks in the same bank group. That is, after sending a command (e.g., read, write, etc.) to a bank in a bank group, the host device will wait t_{CCDL} CLK cycles (e.g., 4 CLK cycles in related art SiPs) before scheduling another read or write command to a bank in the same bank group within the same t_{CCDL} CLK cycle period. With respect to the timing parameter t_{CCDS}, after a read or write command to a bank in a bank group, the host device will wait t_{CCDS} CLK cycles before scheduling another read or write command to a bank in a different bank group. The host device will not violate the timing protocols when scheduling memory commands to the HBM device. That is, the host device will wait at least the number of cycles specified by a timing parameter before issuing successive commands that implicate a timing parameter (e.g., certain timing parameters specify a minimum number of cycles in between commands of certain types). Those skilled in the art understand the interface protocol between the host device and the HBM device and thus, for brevity, will not be further discussed except as needed to explain embodiments of the present disclosure.

As seen in timing diagram 200, the t_{CCDL} CLK cycle period is set to 4 CLK cycles and the t_{CCDS} CLK cycle period is set to 2 CLKs. The timing parameters are set to ensure that the timings of the memory arrays in the dies, the timing through the TSV bus, and the timings of the DQ bus are synchronized to ensure proper operation of the HBM device. For example, in a related art HBM device having a CLK frequency of 2 GHz and a bitrate of 8 gigabits per second (Gbps) (using a burst length of 8), the t_{CCDL} CLK cycle period is set to 4 CLK cycles and the t_{CCDS} CLK cycle period is set to 2 CLK cycles to synchronize data transfer between an HBM device and a host device so as to keep the DQ bus saturated (e.g., DQ bus for PC0, channel 0). That is, as seen in FIG. 2, to maintain the 8 Gbps rate, the DQ bus corresponding to a channel or pseudo-channel is available for write operations every 2 CLK cycles (e.g., a new set of 32-byte pseudo-channel data is available for transmission on the DQ bus every 2 CLK cycles). Similarly, for read operations (not shown), the DQ bus will be available to receive new 32-byte pseudo-channel data every 2 CLK cycles.

As seen in FIG. 2, two BGs can be accessed during the t_{CCDL} CLK cycle period (4 CLK cycles), such as, for example, bank 2 in BG3 and bank 3 in BG7. Once the W1 write command to bank 2 in BG3 is issued, the host device (e.g., host device 120) will wait t_{CCDS} CLK cycles (2 CLK cycles) before issuing the W2 write command to bank 3 in BG7. Depending on how the bank groups are arranged in the HBM device, BG3 and BG7 can be in the same stack or in different stacks. As seen in FIG. 2, the two write commands to BG3 and BG7 take t_{CCDL} CLK cycles (4 CLK cycles). So, t_{CCDL} CLK cycles after scheduling the write command W1 to BG3, the host device can schedule another write command to a different bank in BG3, if needed. Prior to the completion of t_{CCDL} CLK cycles after the first command, the host device will not issue another command to the same bank group.

For purposes of explanation, it is assumed that BG3 and BG7 use the same TSV bus (e.g., same set of TSVs corresponding to PC0, CH0) for communicating with the DQ bus (e.g., DQ bus for PC0, CH0). Also, for clarity, the W1 data flow and the W2 data flow are identified with hashed lines going in different directions. At time TO, based on a write command W1 to bank 2 of BG 3 with a BL of 8, 32 bytes of data are transmitted using 2 CLK cycles (4 WCK cycles) to the DQ bus. At time T1, the W1 data is transferred to bank 2 over the TSV bus, which communicatively couples to BG3. As seen in FIG. 2, the transmission to bank 2 of BG 3 takes t_{CCDS} CLK cycles (2 CLK cycles). Still at time T1, based on a write command W2 to bank 3 of BG 7, 32 bytes of data are transmitted to the DQ bus after W1 data transfer to the DQ bus has finished. At time T2, the W1 data is finished transferring over the TSV bus for BG 3. The W1 data transfer over the TSV bus takes t_{CCDS} CLK cycles (2 CLK cycles), at which point the TSV bus is free to be used for another transfer. At time T2, the W2 data is transferred over the TSV bus, which communicatively couples to BG 7. In the related art system of FIG. 2, the HBM device uses a t_{CCDL} CLK cycle period of 4 CLK cycles and a t_{CCDS} CLK cycle period of 2 CLK cycles to ensure that the memory array timing, the TSV bus timing, the DQ bus timing are synchronized, so that data is not lost and the DQ bus is saturated.

There is, however, a need to increase bandwidth of the communication between the host device and the HBM device on, e.g., communication channels 350 (e.g., from a data rate of 8 Gbps to greater than 8 Gbps such as, for example, 16 Gbps, 24 Gbps, 32 Gbps or more). Details on HBM devices, SiP devices having HBM devices, and associated systems and methods consistent with the present disclosure are set out below. For ease of reference, simplified assemblies of semiconductor packages (and their components) are described herein. It is to be understood, however, that the semiconductor assemblies (and their components) can be moved to, and used in, different spatial orientations without changing the structure and/or function of the disclosed embodiments of the present technology. Additionally, embodiments of the semiconductor packages (and their components) are sometimes described herein with reference to control, read, and/or write signals. It is to be understood, however, that the signals can be described using other terminology and/or the embodiments can use other types of signals that are not discussed without changing the structure and/or function of the disclosed embodiments of the present technology.

To achieve increased bandwidth, more BGs can be opened up (e.g., per channel or per pseudo-channel) for read/write operation during, for example, the t_{CCDL} CLK cycle period and the data rate at the DQ pins can be increased accordingly. However, one potential issue is that, because the data paths in the HBM device operate at tight timing margins, an increase in the data rate at the DQ pins can result in a slip in the timing margins. That is, an increased data rate can mean that the memory array timing, the TSV bus timing, and/or the DQ bus timing are no longer synchronized. A solution can be to increase the t_{CCDS} and t_{CCDR} CLK cycle periods (e.g., setting them to 3 or 4 CLK cycles instead of 2 CLK cycles) to ensure data is not lost when transferring from/to the DQ bus, which operates at a timing of t_{CCDS} CLK cycles (2 CLK cycles) based on external requirements. However, by waiting extra CLK cycles, the data transfers in the HBM device can be less efficient because the DQ bus may no longer be saturated (e.g., gaps or bubbles may exist when there is no data to process).

Another potential issue is that memory array timings are set such that read/write operations on a BG require access to the TSV bus for a predetermined period of time. For example, a related art HBM device can perform read/write operations at an 8 Gbps data rate on two BGs during a t_{CCDL} CLK cycle period (see FIG. 2). For each read/write operation, the memory array timings require access to the appropriate TSV bus for 2 CLK cycles (1 ns) before the TSV bus can be released for the next read/write operation. Thus, the t_{CCDL} CLK cycle period in the related art HBM device is set to 4 CLK cycles (2 ns) to accommodate the two BGs opened during the t_{CCDL} CLK cycle period. Accordingly, with a t_{CCDL} CLK cycle period of 4 CLK cycles (time duration of 2 ns) and a t_{CCDS} CLK cycle period of 2 CLK cycles (time duration of 1 ns), the memory array timing is synchronized with the TSV bus timing and the DQ bus timing in the related art HBM device.

If the number of BGs and the data rate at the DQ bus are increased in order to increase bandwidth in an HBM device, the memory array timings will no longer be synchronized with the TSV bus timings and/or the DQ bus timings. For example, if the data rate is doubled from 8 Gbps to 16 Gbps, with a t_{CCDL} CLK cycle period of 4 CLK cycles and a t_{CCDS} CLK cycle period of 2 CLK cycles, the t_{CCDL} time duration will go from 2 ns to 1 ns and the t_{CCDS} time duration will go from 1 ns to 0.5 ns. As discussed above, the memory array timings are synchronized when the t_{CCDL} time duration is 2 ns and the t_{CCDS} time duration is 1 ns. While the TSV bus frequency can be increased to match the higher data rate and keep the t_{CCDS} CLK cycle period at 2 CLK cycles, the memory arrays may not be able to cycle through the increased number of bank groups in less than 2 ns, and changing the timing in the memory array architecture to match a t_{CCDL} of 1 ns may not be feasible and/or cost effective because of its complexity.

A potential option that may allow the t_{CCDL} CLK cycles to remain at 4 CLK cycles (a time duration of 1 ns) is to open two bank groups for access at the same time. This option keeps the memory array timing in synchronization and also accommodates the increased data rate. However, such a design means that the two bank groups are fixedly paired and must be accessed as a single unit. This configuration effectively reduces the number of independently addressable bank groups and thus reduces the flexibility of the HBM device memory scheduler in selecting memory banks during read/write operations. Accordingly, it is desirable to increase the bandwidth of HBM devices without changing the memory array structure of related art HBM devices (e.g., HBM devices following the JEDEC Standard, High Bandwidth Memory DRAM (HBM4) Specification) and/or changing the number of addressable bank groups.

Embodiments of the present disclosure enable an increased bandwidth in comparison to related art HBM devices by modulating a timing ratio of t_{CCDL}/t_{CCDS} to be greater than 2. Related art HBM systems typically have fixed t_{CCDL}/t_{CCDS} ratio of 2. However, by changing one or both of timing parameters t_{CCDL} and t_{CCDS} appropriately, the timing ratio can be modulated to increase the bandwidth in the HBM device with little to no changes to the physical architecture of a related art HBM device. For example, the timing parameters can be changed in firmware and/or the basic input/output system (BIOS) of the HBM device. The changes to the timing parameters t_{CCDL} and t_{CCDS} represent specification changes and can be done in the firmware and/or the BIOS of the HBM device. By changing one or both timing parameters, the timing ratio can be changed to increase the bandwidth. From the point of view of the host device, the timing ratio change represents an architectural change because the timing ratio defines an effective bandwidth for the HBM device.

To increase timing ratio, the t_{CCDL} CLK cycle setting can be increased, which allows the memory arrays to cycle through more bank groups during a t_{CCDL} CLK cycle period. That is, the number of bank groups that can be accessed per t_{CCDL} CLK cycle period can be increased (e.g., per channel or per pseudo-channel) by scaling the setting for the t_{CCDL} CLK cycle period appropriately. For example, if the memory array timing is such that, at a data rate of 8 Gbps, 2 BGs can be accessed during a t_{CCDL} CLK cycle period of 4 CLK cycles (time duration of 2 ns), then, for the same time duration of 2 ns, doubling the data rate to 16 Gbps and the t_{CCDL} CLK cycle setting to 8 CLK cycles allows access to 4 BGs, and tripling the data rate to 24 Gbps and the t_{CCDL} CLK cycle setting to 12 CLK cycles allows access to 6 BGs, and so on. Thus, in contrast to related art HBM devices that only open two BGs, in embodiments of the present disclosure, three or more BGs can be opened (e.g., per channel or per pseudo-channel) during a given t_{CCDL} CLK cycle period (e.g., a CLK cycle period corresponding to a time duration of 2 ns) to increase the bandwidth of the HBM device.

While the t_{CCDS} CLK cycle setting can also be changed to increase the timing ratio and thus the bandwidth, the adjustments to t_{CCDS} may be more limited than for t_{CCDL}. This is because the timing parameter t_{CCDS} may be based on external communications requirements for the DQ bus, such as, for example, the data rate with a host device, and/or physical limitations of the TSV bus. In some embodiments, the t_{CCDS} CLK cycle period is set to keep the DQ bus saturated and to synchronize the timings between the DQ bus and the TSV bus. For example, in some embodiments, t_{CCDS} CLK cycle period is set to 2 CLK cycles.

Accordingly, by appropriately changing the timing ratio setting, the t_{CCDL} CLK cycle setting, and/or the t_{CCDS} CLK cycle setting, the bandwidth of an HBM device can be increased without altering the memory array timing of the DRAMs. For example, in some embodiments, an HBM device can have a data rate of 16 Gbps with a system clock CLK frequency of 4 GHz. The number of BGs that are opened (e.g., per channel or per pseudo-channel) can be 4 to accommodate the increased bandwidth and the t_{CCDL} CLK cycle period can be set to 8 CLK cycles (time duration of 2 ns) to accommodate the 4 BGs. In addition, in some embodiments, t_{CCDS} CLK cycle period is set at 2 CLK cycles (time duration of 0.5 ns) based on the 16 Gbps data rate to keep the DQ bus saturated and keep the DQ bus and TSV bus synchronized. Because the t_{CCDL} time duration is maintained at 2 ns by increasing the t_{CCDL} CLK cycle period to 8 CLK cycles, the memory array timing need not be changed to accommodate the higher bandwidth of embodiments of the present disclosure. Additional details of embodiments of the present disclosure are discussed below.

In the following discussion, reference will be made to DQ pins, channels, pseudo-channels, and corresponding TSVs. Those skilled in the art understand that, depending on the architecture of the HBM device, the number of TSVs per DQ pin can be a relationship that is something other than a one-to-one ratio. For example, based on a burst length (BL) of 8, there can be 8 TSVs per DQ pin. Depending on the design, other HBM devices can have other TSVs/DQ pin ratios such as, for example, 4 TSVs/DQ pin, 1 TSV/DQ pin, etc. Accordingly, while the following discussion focuses on TSV buses and DQ pins, those skilled in the art understand that more than one TSV can correspond to a DQ pin even if not explicitly stated. In addition, in the following discussion, the TSV bus and/or the DQ bus can correspond to, for example, a channel, a pseudo channel, or some other grouping of data lines.

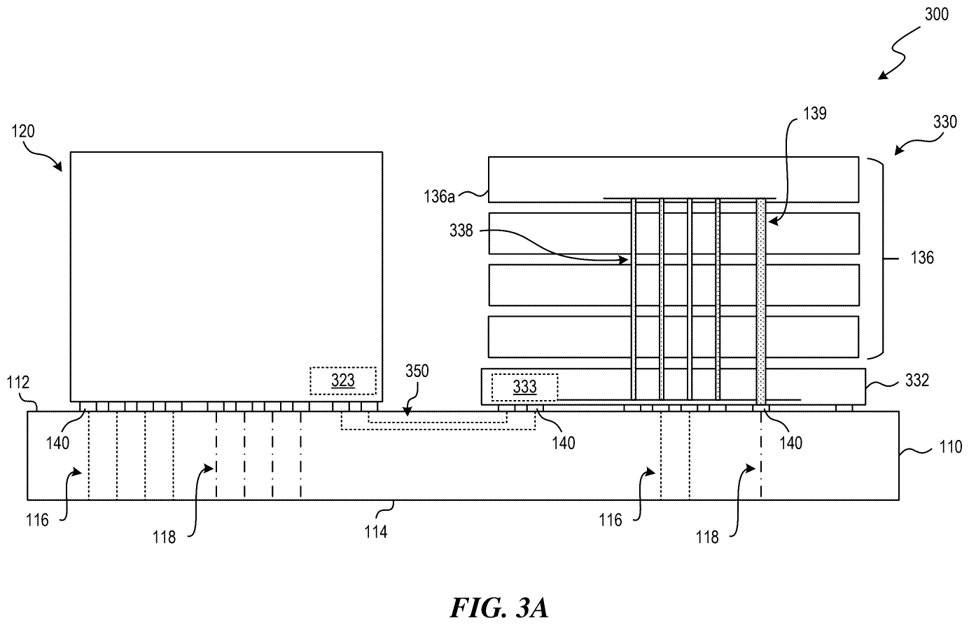

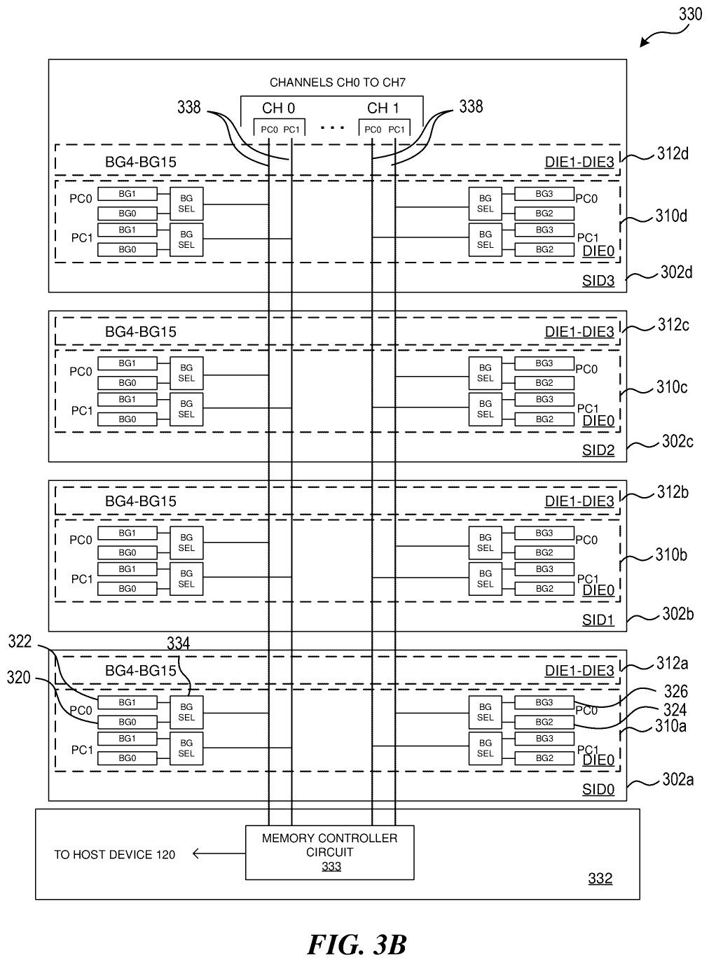

FIG. 3A is a partially schematic cross-sectional diagram of an embodiment of a SiP device 300 that is consistent with the present disclosure. SiP device 300 is similar to SiP device 100 and components that are the same are identified with the same reference numbers. Accordingly, the functions of those components will not be discussed further. Host IO circuit 323, HBM memory controller circuit 333, interface die 332, signal TSVs 338, and communication channel 350 have the same functions as Host IO circuit 123, HBM memory controller circuit 133, interface die 132, signal TSVs 138, and communication channel 150, respectively, as discussed above with respect to FIG. 1. However, in some embodiments, these components can be configured to and/or may include different circuits to handle an increased data rate (e.g., 16 Gbps, 24 Gbps, 32 Gbps, etc.).

FIG. 3B illustrates a block diagram of the HBM device 330 of FIG. 3A. The illustrated embodiment in FIG. 3B has a 4N architecture in that the HBM device 330 includes four stacks SID0-SID3 (labeled 302a-d, respectively) that can each include four DRAM dies DIE0-DIE3 (die DIE0 in each stack is labeled 310a-d, respectively, and dies DIE1-DIE3, in each stack are collectively labeled 312a-d, respectively). However, other embodiments can have other arrangements in which the number of stacks and/or dies can be fewer or greater. For example, in some embodiments, the number of stacks and/or dies can be 1, 2, or 3.

Each die 310a-d and 312a-d can have one or more channels that provide independent data access to one or more banks of memory arrays (not shown). For example, in the embodiment of FIG. 3B, channels 0 and 1 and the corresponding pseudo-channels PC0 and PC1 for each channel are shown extending through the stacks 302a-d using TSV buses. Each pseudo-channel TSV bus can include one or more TSVs 338 (one TSV 338 on each TSV bus is illustrated in FIG. 3B), depending on the burst length and number of DQ pins in each channel. Die 310a-d in each stack has bank groups BG0 320 and BG1 322 (for clarity, only BG0 and BG1 in stack 302a and die 310a are labeled), which can communicatively couple to channel 0, and bank groups BG2 324 and BG3 326 (for clarity, only BG0 and BG1 in stack 302a and die 310a are labeled), which can communicatively couple to channel 1. Each bank group 320, 322, 324, 326 can include one or more memory banks (e.g., 8 memory banks) that each include one or more memory arrays. The other channels 2-7 (not shown) have similar configurations but communicatively couple to different bank groups in different dies. For example, the other channels may couple to BG4 through BG15.

In some embodiments, each channel 0-7 can be split into two pseudo-channels that operate semi-independently such as, for example, pseudo-channel PC0 corresponding to DQ bits 0-31 and pseudo-channel PC1 corresponding to DQ bits 32-64. The channels and/or pseudo-channels can provide independent access to corresponding BGs, where each BG can include one or more banks. For example, if a die has 16 banks, each BG can have four banks and an independent channel can provide access to that BG. A die can include fewer banks than 16 such as, for example, 4 banks, 8 banks, etc. In some embodiments, a die can include more than 16 banks. Similarly, the number of BGs in a die can be fewer or greater than four. Segmenting a memory device into banks and bank groups is known in the art and thus, for brevity, will not be further discussed. In addition, those skilled in the art understand that an HBM device can have different arrangements with respect to the number of dies, banks, bank groups, channels, and/or pseudo-channels than in the disclosed embodiments and still be consistent with the present disclosure.

The following description focuses on pseudo-channel PC0 in SID0 302a and DIE0 310a. However, the description is applicable to pseudo-channel PC1, the other stacks 302b-d, and the other dies 310b-d and 312a-d, and thus for brevity and clarity is not repeated. As seen FIG. 3B, the bank groups 320, 322, 324, and 326 are each split into two sets, with each set corresponding to a different pseudo-channel (PC0 or PC1). The banks groups 320 and 322 for the PC0 set can selectively and communicatively couple to the TSV bus for PC0 of channel 0. During read or write operations to a bank in either bank group 320 or 322, the HBM memory controller circuit 333 and/or another circuit determines which bank group the bank belongs to. Based on the determination, the HBM memory controller circuit 333 and/or another circuit selects the bank group and operatively couples the bank group to the TSV bus such that the bank group has access to the TSV bus for a period that is based on the t_{CCDS} CLK cycle period, which in some embodiments is 2 CLK cycles. During the t_{CCDS} CLK cycle period, another bank group cannot communicatively couple to that TSV bus.

A BG select circuit 334 (for clarity only the BG select circuit for PC0 in stack 302a of die 310a is labeled) selects which bank group (e.g., 320, 322) should communicatively couple to the TSV bus. In some embodiments, the determination as to which BG should be communicatively coupled to which TSV bus can be performed in the HBM memory controller circuit 333 (an/or another circuit in the HBM device) based on, for example, SID, BG, and/or BA information in the read/write commands. The BG select circuit 334 ensures only one of the bank groups 320 or 322 is communicatively coupled to the TSV bus at any given time. The BG select circuit 334, HBM memory controller circuit 333, and/or another circuit also ensures that the same bank group is not accessed within the t_{CCDL} CLK cycle period. The operational description for bank groups 320 and 322 corresponding to PC1 and the other bank groups 320 and 322 will be similar to that of bank groups 320 and 322 for PC0, and thus, for brevity, will not be discussed. In addition, the bank groups in the other dies 310b-d and 312a-d and in the other stacks 302b-d have similar configurations, and thus for brevity will not be discussed. Although the embodiment in FIG. 3B shows two BGs are first communicatively coupled to BG select circuit that is then communicatively coupled to the TSV bus, in other embodiments, based on the arrangement, each BG can communicatively couple directly to the TSV bus without the intervening BG select circuit. Those skilled in the art understand that the numbering and specific configuration of bank groups and banks can be different from that shown in FIGS. 3A and 3B, but the concepts discussed herein are applicable to other bank group configurations.

For brevity, embodiments having pseudo-channels are described below. However, those skilled in the art understand that the concepts discussed below are also applicable to embodiments where the channels are not split into pseudo-channels.

As seen FIG. 3B, interface die 332 includes the HBM memory controller circuit 333. The HBM memory controller circuit 333 controls external access to the DQ bus (e.g., from host device 120) and manages the DQ signals to and from the TSV bus based on the memory operation (e.g., read, write, etc.). Configuration and operation of HBM memory controller circuits are known to those skilled in the art and thus, for brevity, will not be discussed further.

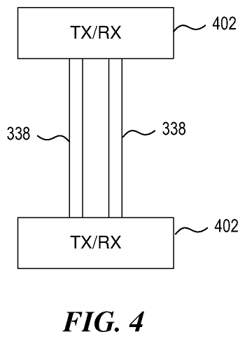

In the related art HBM device, the DQ bus and the TSV bus are synchronized so that the data rate through the buses are the same. For example, for an 8 Gbps data rate, the DQ bus and TSV bus timings are set based on the t_{CCDS} CLK cycle period, which is at 2 CLK cycles. The 2 CLK cycles correspond to a 1 ns transmission time through the TSV. However, if the data rate is increased, for example, doubled to 16 Gbps, the 2 CLK cycles now corresponds to a TSV bus transmission time of 0.5 ns. To keep the DQ bus and TSV bus synchronized, the frequency of the TSV bus must be increased to match that of the DQ bus. However, to drive the frequency higher, the transmitter and receiver circuits for the TSVs may have to be driven at a higher voltage. If the voltage is not high enough, the voltage swing between low and high voltage may not be fast enough due the electrical characteristics (e.g., resistance, inductance, ands capacitance) of the TSVs. For example, as seen in FIG. 4, the DQ signal TSVs 338 are driven by transmit/receive circuits 402 at each end of the TSV bus. If the voltage swing (between low and high voltage) of the signal in the TSV 338 is not fast enough at the higher frequency (e.g., 16 Gbps. 24 Gbps, 32 Gbps, etc.) due to the resistance, inductance, and/or capacitance characteristics of the TSV bus, the data carried by the signal will be corrupted. In such cases, the voltage setting at transmit/receive circuits 402 may need to be increased and/or low voltage swing signaling in the HBM device may need to be disabled. Accordingly, in some embodiments of the present disclosure, along with setting the TSV bus frequency to match that of the DQ bus, the transmit/receive circuits 402 of the TSV bus are configured such that the voltage source used to drive the signals through the TSB bus provides the proper voltage swing. For example, the voltage source in the transmit/receive circuits 402 can be configured to provide an upper voltage that is a range of 0.8 volts to 1.2 volts.

In some embodiments, to lower the power consumption and/or to aid in driving the TSV bus at the higher frequency, the dimensions of the TSVs can be changed to provide better electrical characteristics (e.g., resistance, inductance, and/or capacitance). For example, the diameter of the TSV can be in a range of 5 μm to 10 μm and the conductive materials used in the TSV bus can include one or more of copper, tungsten, and doped polysilicon.

In operation, in some embodiments, the HBM memory controller circuit 333 and/or another circuit can select different bank groups from the stacks 302a-d in order to perform read or write operations during the t_{CCDL} CLK cycle period (e.g., 8 CLK cycles, 12 CLK cycles, 16 CLK cycles, etc.). For example, for a first t_{CCDS} CLK cycle period (e.g., 2 CLK cycles) within a t_{CCDL} CLK cycle period, the HBM memory controller circuit 333 can receive a read or write command corresponding to a bank. The HBM memory controller circuit 333 then determines the bank group corresponding to the bank and communicatively couples the bank group to the TSV bus for the duration of the t_{CCDS} CLK cycle period. Then, in each of the following t_{CCDS} CLK cycle periods (within the t_{CCDL} CLK cycle period period), the process repeats for a different bank until the t_{CCDL} CLK cycle period ends. The different bank groups can correspond to the same channel (e.g., channel 0-7) or the same pseudo-channel (e.g., PC0 or PC1 for channel 0-7). During read or write operations, the HBM memory controller circuit 333 can selectively and communicatively couple the selected bank groups to the TSV bus corresponding to the channel or pseudo-channel. That is, each selected bank group is communicatively coupled to TSV bus one at a time to perform read or write operations to the appropriate bank. In some embodiments, each selected bank group is communicatively coupled to the TSV bus for duration of the respective t_{CCDS} CLK cycle period. In addition, in some embodiments, the timing parameters t_{CCDL} and t_{CCDS} are set such that the timing ratio is greater than 2.

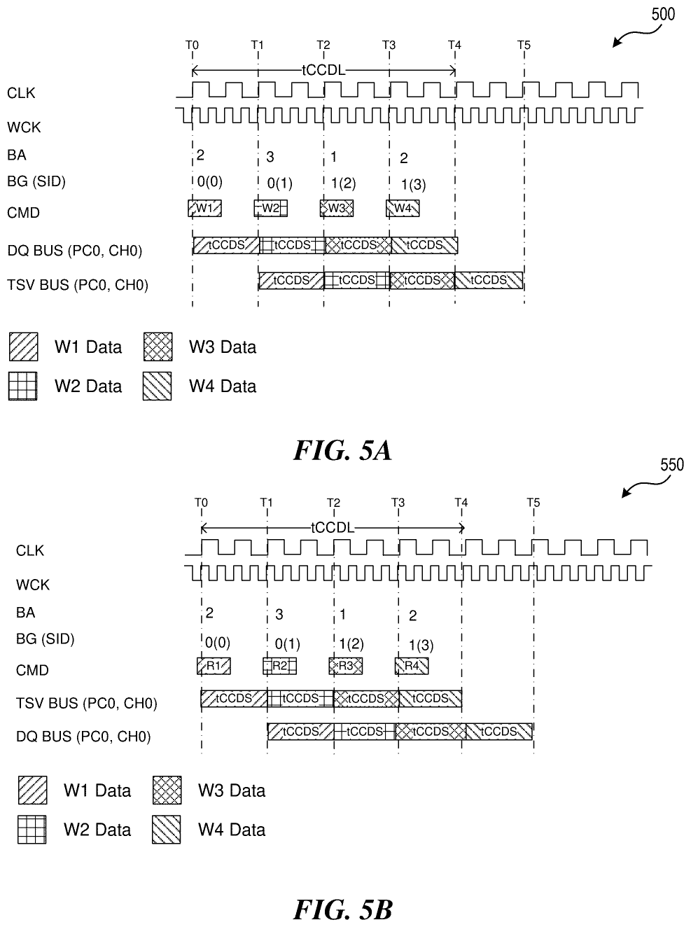

The timing diagrams of FIGS. 5A and 5B can correspond to an HBM device that has a data rate of 16 Gbps. As seen in FIGS. 5A and 5B, four bank groups can be selected for access to perform read or write operations during a t_{CCDL} CLK cycle period, which can be set at 8 CLK cycles to accommodate the four bank groups. As an illustrative example, the four bank groups can be BG 320 in die 310a, BG 320 in die 310b, BG 322 in die 310c, and BG 322 in die 310d which correspond to PC0 of channel 0). In some embodiments, the t_{CCDS} CLK cycle period can beset to 2 CLK cycles based on external communication requirements and to keep the DQ bus saturated. As seen in the diagram, the commands are separated by the t_{CCDS} CLK cycles (2 CKL cycles). In addition, to match the data rate of the DQ bus, the TSV bus timing is also set at 2 CLK cycles. In this embodiment, with the data rate at 16 Gbps, a t_{CCDL} CLK cycle period set at 8 CLK cycles corresponds to 2 ns time duration. With the t_{CCDL} time duration at 2 ns, the memory array timing of the related art HBM device discussed above does not need to be changed. Accordingly, in the above embodiment, the DQ bus timing, TSV bus timing, and the memory array timing are all synchronized.

FIG. 5A illustrates a simplified timing diagram 500 for write operations that are consistent with the present disclosure. As seen in the diagram and discussed further below, once a write command (e.g., write command W1) is issued by the host device (e.g., host device 120), the host device will wait t_{CCDS} CLK cycles (2 CLK cycles) before issuing another write command (e.g., write command W2) to a different bank group. For example, the W1 command writes to BG0/SID0 and the W2 command writes to BG0/SID1, which is a different bank group than BG0/SID0 because it is different stack (but the consecutive write commands can also be to different BGs in the same SID). As seen in FIG. 5A, there are four consecutive commands (read or write) that take t_{CCDL} CLK cycles (8 CLK cycles) to process. So, at time T4, after the t_{CCDL} CLK cycle period has completed, the host device can issue a write command to a different bank in BG0/SID0, if needed. Prior to the completion of t_{CCDL} CLK cycle period, the host device will not issue a command to the same bank group. For clarity, the different W #data flows are identified using different hashlines and crosshatches.

The time from T0 to T4 corresponds to the timing parameter tCC_{DL}, which is 8 CLK cycles in this embodiment. As seen in FIG. 5A, 4 BGs can be opened (e.g., per channel or per pseudo-channel) for write operations during the t_{CCDL} CLK cycle period, which allows for more bandwidth than related art devices that only open 2 BGs. In the following embodiment, the banks being written to correspond to PC0 of channel 0 and thus, the TSV bus corresponds to PC0 of channel 0.

At time TO, based on a write command W1 to bank 2 of BG0 in SID0 with a BL of 8, 32 bytes of data are transmitted using 2 CLK cycles (4 WCK cycles) to the DQ bus from, for example, the host device 120 via HBM memory controller circuit 333. The 32-bytes for W1 can correspond to a pseudo-channel PC0 of channel 0 (e.g., based on the PC bit information in the address signal). At time T1, the W1 data is transferred to bank 2 over the TSV bus. As seen in FIG. 5A, once the transmission starts, the bank 2 has access to the TSV bus for t_{CCDS} CLK cycles, which in this case is 2 CLK cycles. In this embodiment, the 2 CLK cycles correspond to 0.5 ns, which means that the TSV bus is at the same data rate as the DQ bus.

Still at time T1, based on a write command W2 to bank 3 of BG 0 in SID1, 32 bytes of data are transmitted to the DQ bus after data transfer to the DQ bus for the write command W1 has finished. At time T2, the W1 data has completed the transfer over the TSV bus for BG 0 in SID0, and the W2 data is transferred to bank 3 over the TSV bus. Similar to the W1 write operation, once the transmission starts, bank 3 has access to the corresponding TSV bus for t_{CCDS} CLK cycles (2 CLK cycles).

Still at time T2, based on a write command W3 to bank 1 of BG 1 in SID2, 32 bytes of data are transmitted to the DQ bus after the W2 data transfer to the DQ bus has finished. At time T3, the W2 data has completed the transfer over the TSV bus for BG 0 in SID1, and the W3 data is transferred to bank 1 over the TSV bus. Similar to the other write operations, once the transmission starts, bank 1 has access to the TSV bus for t_{CCDS} CLK cycles (2 CLK cycles).

Still at time T3, based on a write command W4 to bank 2 of BG 1 in SID3, 32 bytes of data are transmitted to the DQ bus after the W3 data transfer to the DQ bus has finished. At time T4, W3 data has completed the transfer over the TSV bus for BG 1 in SID2, and the W4 data is immediately transferred to bank 2 over the TSV bus. Similar to the other write operations, once the transmission starts, bank 2 has access to the TSV bus for t_{CCDS} CLK cycles (2 CLK cycles). At time T5, the W4 data transfer to bank 2 of BG1 in SID3 has completed and the TSV bus is released.

FIG. 5B illustrates a simplified timing diagram 550 for read operations that are consistent with the present disclosure. As seen in the diagram and discussed further below, once a read command (e.g., read command R1) is issued by the host device (e.g., host device 120), the host device will wait t_{CCDS} CLK cycles (e.g., 2 CLK cycles) before issuing another read command (e.g., read command R2) to a different bank group. For example, the R1 command reads from BG0/SID0 and the R2 command reads from BG0/SID1, which is a different bank group than BG0/SID0 because it is different stack (but the consecutive read commands can also be to different BGs in the same SID). As seen in 5B, there are four consecutive read commands that take t_{CCDL} CLK cycles (8 CLK cycles) to complete. So, at time T4, after the t_{CCDL} CLK cycle period has completed, the host device can issue a command to a different bank in BG0/SID0, if needed. Prior to the completion of t_{CCDL} CLK cycle period, the host device will not issue a command to the same bank group. For clarity, the different R #data flows are identified using different hashlines and crosshatches.

The time from T0 to T4 corresponds to the timing parameter t_{CCDL}, which is 8 CLK cycles in this embodiment. As seen in FIG. 5B, 4 BGs can be opened (e.g., per channel or per pseudo-channel) for read operations during the duration t_{CCDL}, which allows for more bandwidth than related art devices that only open 2 BGs. In the following embodiment, the banks being read from correspond to PC0 of channel 0 and thus, the TSV bus corresponds to PC0 of channel 0.

At time T0, based on a read command R1, 32 bytes of data (BL of 8) are read from bank 2 of BG 0 in SID0 and sent to the TSV bus. As seen in FIG. 5B, once the transmission starts, bank 2 has access to the TSV bus for t_{CCDS} CLK cycles, which in this case is 2 CLK cycles.

At time T1, the R1 data from bank 2 has completed the transfer to the TSV bus, and, based on a read command R2, 32 bytes of data are read from bank 3 of BG 3 in SID1 and sent to the TSV bus. As seen in FIG. 5B, once the transmission starts, bank 3 has access to the TSV bus for t_{CCDS} CLK cycles (2 CLK cycles). Still at time T1, the R1 read data is made available on the DQ bus for t_{CCDS} CLK cycles (2 CLK cycles) for transfer to, for example, the host device 120 via HBM memory controller circuit 333.

At time T2, the R2 data from bank 3 has completed the transfer over the TSV bus, and based on a read command R3, 32 bytes of data are read from bank 1 of BG 1 in SID2 for transfer over the TSV bus. Once the transmission starts, bank 1 has access to the TSV bus for t_{CCDS} CLK cycles (2 CLK cycles). Still at time T2, the R2 read data is made available on the DQ bus for a duration of t_{CCD}S CLK cycles (2 CLK cycles) for transfer to, for example, the host device 120 via HBM memory controller circuit 333.

At time T3, the data from bank 1 has completed the transfer over the TSV bus, and based on a read command R4, 32 bytes of data are read from bank 2 of BG 1 in SID3 for transfer over the TSV bus. Once the transmission starts, bank 2 has access to the TSV bus for t_{CCDS} CLK cycles (e.g., 2 CLK cycles). Still at time T3, the R3 read data is made available on the DQ bus for t_{CCDS} CLK cycles (e.g., 2 CLK cycles) for transfer to, for example, the host device 120 via HBM memory controller circuit 333.

At time T4, the R4 read data transfer over the TSV bus from bank 2 of BG1 in SID3 is finished and the TSV bus is released. The R4 read data is made available on the DQ bus for a duration of t_{CCDS} CLK cycles (2 CLK cycles) until time T5 for transfer to, for example, the host device 120 via HBM memory controller circuit 333.

As seen in FIGS. 5A and 5B, in embodiments of the present disclosure, the bandwidth can be increased while keeping the DQ bus saturated during read/write operations and while operating at a t_{CCDS} CLK cycle period equal to 2 CLK cycles.

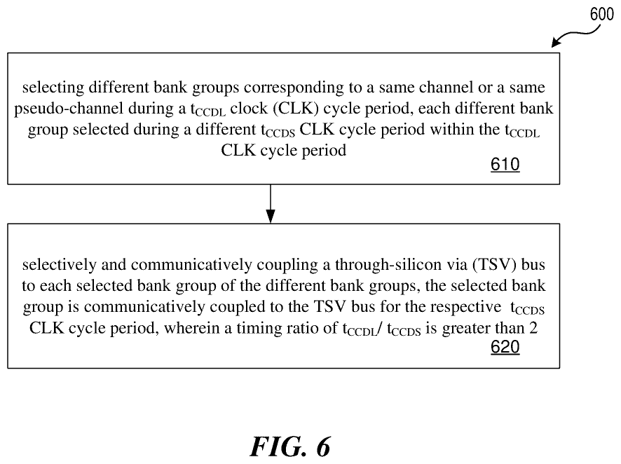

FIG. 6 illustrates a flow chart 600 showing the method steps performed by one or more processors and/or hardwired circuitry in the HBM device such as, for example, the HBM memory controller circuit 333 and/or some other circuit or circuits. In step 610, the HBM device selects different bank groups corresponding to a same channel or a same pseudo-channel during a t_{CCDL} time period, each different bank group selected during a different t_{CCDS} CLK cycle period within the t_{CCDL} CLK cycle period. For example, as discussed above, the HBM memory controller circuit 333 can select from bank groups 320 and 322 in dies 310a-d in respective stacks 302a-d during a t_{CCDS} CLK cycle period in order to perform read or write operations (see FIGS. 5A and 5B). As discussed above, the t_{CCDL} CLK cycle period can be set at 8 CLK cycles.

In step 620, the HBM device selects and communicatively couples a through-silicon via (TSV) bus to each selected bank group of the different bank groups, where the selected bank group is communicatively coupled to the TSV bus for the respective t_{CCDS} CLK cycle period, and where a timing ratio of t_{CCDL}/t_{CCDS} is greater than 2. As discussed above, based on which bank is being read or written to, the HBM memory controller circuit 333 selects the appropriate bank group and communicatively couples the TSV bus to the appropriate bank group. As discussed above, the TSV bus and DQ bus timing are set to 2 CLK cycles. Thus, the ratio of t_{CCDL}/t_{CCDS} is 8/2, which equals 4 and greater than 2.

From the foregoing, it will be appreciated that embodiment of the present disclosure provide increased bandwidth over related art HBM devices while ensuring that the DRAM memory array timings, the TSV bus timings, and the DQ bus timings are all synchronized. For example, it will be appreciated that, in some embodiment, the data rate at the DQ pins are increased while still keeping the same memory array as related art HBM devices. In addition, embodiments of the present disclosure increase the number of bank groups that can be opened during a t_{CCDL} CLK cycle time period in comparison to a related art HBM device, while still maintaining a 4N architecture and the same number of banks.

In addition, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “generally”, “approximately,” and “about” are used herein to mean within at least within 10 percent of a given value or limit. Purely by way of example, an approximate ratio means within ten percent of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Thus, computer-readable media can comprise computer-readable storage media (e.g., “non-transitory” media) and computer-readable transmission media.

It will also be appreciated that various modifications may be made without deviating from the disclosure or the technology. For example, the dies in the HBM device can be arranged in any other suitable order (e.g., with the non-volatile memory die(s) positioned between the interface die and the volatile memory dies; with the volatile memory dies on the bottom of the die stack; and the like). Further, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. For example, although discussed herein as using a non-volatile memory die (e.g., a NAND die and/or NOR die) to expand the memory of the HBM device, it will be understood that alternative memory extension dies can be used (e.g., larger-capacity DRAM dies and/or any other suitable memory component). While such embodiments may forgo certain benefits (e.g., non-volatile storage), such embodiments may nevertheless provide additional benefits (e.g., reducing the traffic through the bottleneck, allowing many complex computation operations to be executed relatively quickly, etc.).

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A system-in-package (SiP) device, comprising:
a base substrate;
a processing unit carried by the base substrate; and
a high bandwidth memory (HBM) device carried by the base substrate and electrically coupled to the processing unit,
wherein the HBM device comprises:
one or more stacks, each stack having one or more dies, wherein each die comprises one or more bank groups, each bank group comprises one or more banks, and each bank comprising one or more memory arrays; and
an interface die, the interface die comprising a HBM memory controller circuit configured to select different bank groups corresponding to a same channel or a same pseudo-channel during a t_{CCDL} clock (CLK) cycle period, each different bank group selected during a different t_{CCDS} CLK cycle period within the t_{CCDL} CLK cycle period,
wherein the HBM memory controller circuit is configured to selectively and communicatively couple a TSV bus to each selected bank group of the different bank groups, and the selected bank group is communicatively coupled to the TSV bus for a duration of the respective t_{CCDS} CLK cycle period,
wherein a timing ratio of t_{CCDL}/t_{CCDS} is greater than 2, and
wherein t_{CCDL} corresponds to a delay between commands associated with different banks in a same bank group, and t_{CCDS} corresponds to a delay between commands associated with different banks in different bank groups.

2. The SiP device of claim 1, wherein the timing ratio t_{CCDL}/t_{CCDS} is 4 and a data rate of the TSV bus is 16 gigabits per second (Gbps).

3. The SiP device of claim 1, wherein the t_{CCDL} duration is 8 CLK cycles and the t_{CCDS} CLK cycle period is 2 CLK cycles.

4. The SiP device of claim 1, wherein at least one of the t_{CCDL} CLK cycle period and the t_{CCDS} CLK cycle period is set in at least one of a firmware or a BIOS of the HBM device.

5. The SiP device of claim 1, wherein the different bank groups comprise four different bank groups, and wherein a data rate of the TSV bus is 16 Gbps.

6. The SiP device of claim 1, wherein the TSV bus is driven at a same data rate as that of a DQ bus, and wherein the data rate of the TSV bus is 16 Gbps data rate.

7. The SiP device of claim 6, wherein a voltage source used to drive signals through the TSV bus provides an upper voltage in a range of 0.8 volts to 1.2 volts.

8. A high bandwidth memory (HBM) device, comprising:
one or more stacks, each stack having one or more dies, wherein each die comprising one or more bank groups, each bank group comprising one or more banks, and each bank comprising one or more memory arrays; and
an interface die, the interface die comprising a HBM memory controller circuit configured to select different bank groups corresponding to a same channel or a same pseudo-channel during a t_{CCDL} clock (CLK) cycle period, each different bank group selected during a different t_{CCDS} CLK cycle period within the t_{CCDL} CLK cycle period,
wherein the HBM memory controller circuit is configured to selectively and communicatively couple a through-silicon via (TSV) bus to each selected bank group of the different bank groups, and the selected bank group is communicatively coupled to the TSV bus for a duration of the respective t_{CCDS} CLK cycle period,
wherein a timing ratio of t_{CCDL}/t_{CCDS} is greater than 2, and
wherein t_{CCDL} corresponds to a delay between commands associated with different banks in a same bank group, and t_{CCDS} corresponds to a delay between commands associated with different banks in different bank groups.

9. The HBM device of claim 8, wherein the timing ratio t_{CCDL}/t_{CCDS} is 4 and a data rate of the TSV bus is 16 gigabits per second (Gbps).

10. The HBM device of claim 8, wherein the t_{CCDL} time period is 8 CLK cycles and the t_{CCDS} time period is 2 CLK cycles.

11. The HBM device of claim 8, wherein at least one of the t_{CCDL} CLK cycle period and the t_{CCDS} CLK cycle period is set in at least one of a firmware or a BIOS of the HBM device.

12. The HBM device of claim 8, wherein the different bank groups comprise four different bank groups, and wherein a data rate of the TSV bus is 16 Gbps.

13. The HBM device of claim 8, wherein the TSV bus is driven at a same data rate as that of a DQ bus, and wherein the data rate of the TSV bus is 16 Gbps data rate.

14. The HBM device of claim 13, wherein a voltage source used to drive signals through the TSV bus provides an upper voltage in a range of 0.8 volts to 1.2 volts.

15. A method, comprising:
transmitting, from a host device, a first command to a high bandwidth memory (HBM) device communicatively coupled to the host device, wherein the first command is associated with a first bank group and a first bank; and
transmitting, from the host device, a second command to the HBM device, wherein the second command is associated with the first bank group and a second bank,
wherein the host is configured to transmit the second command no less than t_{CCDL} cycles after transmitting the first command;
wherein a timing ratio of t_{CCDL} cycles to a number of minimum cycles between commands to different bank groups is greater than 2.

16. The method of claim 15, wherein the timing ratio is 4 and a communication data rate between the host device and the HBM device is 16 gigabits per second (Gbps).

17. The method of claim 15, wherein the t_{CCDL} cycles is 8 clock (CLK) cycles and the number of minimum cycles between commands to different bank groups is 2 CLK cycles.

18. The method of claim 15, wherein at least one of the t_{CCDL} cycles and the number of minimum cycles between commands to different bank groups is set in at least one of a firmware or a BIOS of the HBM device.

19. The method of claim 15, wherein the different bank groups comprise four different bank groups, and wherein a communication data rate between the host device and the HBM device is 16 Gbps.

20. The method of claim 15, wherein the host device and the HBM device are integrated into a system-in-package (SiP) configuration.
